(19) United States
(12) Patent Application Publication
(10) Pub. No.: US 2014/0090638 A1
(43) Pub. Date: Apr. 3, 2014

(54) SUN TRACKING SYSTEM

(71) Applicant: SUNPOWER CORPORATION, San Jose, CA (US)

(72) Inventor: Tyler Grushkowitz, Hayward, CA (US)

(73) Assignee: SUNPOWER CORPORATION, San Jose, CA (US)

(21) Appl. No.: 13/631,728

(22) Filed: Sep. 28, 2012

(51) Int. Cl. F24J 2/54; H01L 31/18; B23P 11/00

(52) U.S. Cl. CPC F24J 2/541; B23P 11/00; H01L 31/18
USPC 126/605; 29/890.033

(57) ABSTRACT

A sun tracking solar power generation system can include drive members for driving a plurality of parallel sun tracking assemblies. The drive components of the drive system can be arranged in a recess or trench created in the ground. This arrangement can reduce the material and labor costs for constructing a solar power system.

### BACKGROUND OF THE INVENTIONS

1. Field of the Inventions

The present application is directed to sun tracking systems, such as sun tracking photovoltaic installations in which a plurality of parallel rows of photovoltaic modules are driven with a single drive unit so as to pivot about parallel pivot axes.

2. Background

Some known sun tracking photovoltaic solar power systems such as utility-scale, photovoltaic installations, are designed to pivot a large number of solar modules so as to track the movement of the sun using the fewest possible number of driver motors. For example, some known systems include parallel rows of photovoltaic modules supported on torque tubes. The torque tubes can comprise a number of long shafts connected together in an end to end fashion. The torque tubes are supported in an orientation parallel to each other such that their pivot axes are parallel. These shafts are sufficiently long that they must be supported by many vertical columns, known as “piles”.

In some systems, each drive unit includes an electric motor and a controller and is connected to each of the parallel torque tubes with a series of drive struts which are connected in an end to end fashion, in a direction extending transverse to the torque tubes. Each of the torque tubes include a torque arm extending from the torque tube to the drive strut. The electric motor drives the drive strut in an oscillating motion so as to pivot the torque tubes to provide the desired sun tracking movement.

### BRIEF SUMMARY

An aspect of at least one of the inventions disclosed herein includes the realization that large cost savings can be achieved by altering the ground at the site at which a large solar sun tracking photovoltaic system is constructed. During construction of some known systems, the ground at the installation site was altered as little as possible for environmental impact reasons and to reduce construction costs. Thus, in the known systems, the height of the piles was determined by variance required for drive struts to cycle through the sun tracking movement without colliding with the ground.

Using this criteria for the minimum height of the piles creates a significant impact on the design of the entire system. For example, the solar power installations must be designed to withstand expected wind forces that are predetermined for the installation site. When wind blows in a direction transverse to the torque tube, the greatest torques are applied to the piles. The magnitude of the torque is directly affected by the height of the pile. Thus, the higher the pile, the larger the torque.

An aspect of at least one of the inventions disclosed herein includes the realization that by altering the ground so as to create trenches directly below the drive struts, shorter piles can be used. With shorter piles, the torque applied to the piles is less under the loads created by the same wind speeds noted above. On a large solar installation, this can result in a large savings in material costs for the piles, as well as the required depth for driving the piles, the amount of cement or concrete needed to construct sufficient foundations for the piles, as well as the associated labor, and other costs.

Thus, in accordance with an embodiment, a solar array can comprise a pile configured to support a shaft, the pile having a lower end fixed to a ground. At least a first shaft can be supported by the pile such that the shaft can pivot relative to the pile, about a pivot axis, the shaft supporting at least one solar module. At least a first arm having a first and second ends can have its first end connected to the first shaft, the first arm extending from the first end along a substantially radial direction relative to the pivot axis such that the second end of the first arm moves through an arcuate path as the first shaft pivots about the pivot axis. A trench can be formed in the upper surface of the ground wherein the upper surface of the ground surrounding the trench is generally planar, the trench being sized such as the second end moves from at least a first position above the generally planar upper surface of the ground to a second position within the trench and below the upper surface of the ground.

In accordance with another embodiment, a solar array can comprise a pile configured to support a shaft, the pile having a lower end fixed to a ground. At least a first shaft can be supported by the pile such that the shaft can pivot relative to the pile, about a pivot axis, the shaft supporting at least one solar module. At least a first arm having a first and second ends can have its first end connected to the first shaft, the first arm extending from the first end along a substantially radial direction relative to the pivot axis such that the second end of the first arm moves through an arcuate path as the first shaft pivots about the pivot axis. Additionally, the array can include means for allowing the second end to move from at least a first position above the generally planar upper surface of the ground to a second position below the upper surface of the ground without touching a surface of the ground.

In accordance with yet another embodiment, a method of constructing a solar array can be provided. The method can include fixing a pile to a ground and supporting at least a first shaft with the pile such that the shaft can pivot relative to the pile, about a pivot axis, the shaft supporting at least one solar module. The method can also include connecting at least a first arm to the first shaft such that the first arm extends along a substantially radial direction relative to the pivot axis such that the second end of the first arm moves through an arcuate path as the first shaft pivots about the pivot axis. Additionally, the method can include forming a trench in the upper surface of the ground wherein the upper surface of the ground surrounding the trench is generally planar, the trench being sized such as the second end moves from at least a first position above the generally planar upper surface of the ground to a second position within the trench and below the upper surface of the ground.

### BRIEF DESCRIPTION OF THE DRAWINGS

FIG. 1 is a schematic diagram of a prior art sun tracking photovoltaic system, with which the present inventions can be used.

FIG. 2 is a schematic diagram of an electrical system for the photovoltaic system of FIG. 1.

FIG. 3 is a perspective view of the solar collection system of FIG. 1, illustrating a plurality of piles mounted to the ground and supporting a plurality of torque tubes with a sun-tracking drive in accordance with an embodiment;

FIG. 4 is an end view of one of the rows of solar modules of FIG. 3, with the solar module in a maximum tilted position.

FIG. 5 is a perspective view of a sun tracking photovoltaic system in accordance with an embodiment, with all but one of the associated solar modules removed.

FIG. 6 is an end view of one of the rows to solar modules showing the location of a drive system and drive struts positioned within a trench.

FIG. 7 is an end view of one of the rows of solar modules of FIGS. 5 and 6, showing the solar module in a maximum tilted position (in dashed line) and in a “noon” position (in solid line).

### DETAILED DESCRIPTION

The following detailed description is merely illustrative in nature and is not intended to limit the embodiments of the subject matter or the application and uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the proceeding technical field, background, brief summary, or the following detailed description.

Certain terminology may be used in the following description for the purpose of reference only, and thus are not intended to be limiting. For example, terms such as “upper”, “lower”, “above”, and “below” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import. Similarly, the terms “first”, “second”, and other such numerical terms referring to structures do not imply a sequence or order unless clearly indicated by the context.

The inventions disclosed herein are described in the context of non-concentrated and concentrated photovoltaic arrays and modules. However, these inventions can be used in other contexts as well, such as concentrated thermal solar systems, etc.

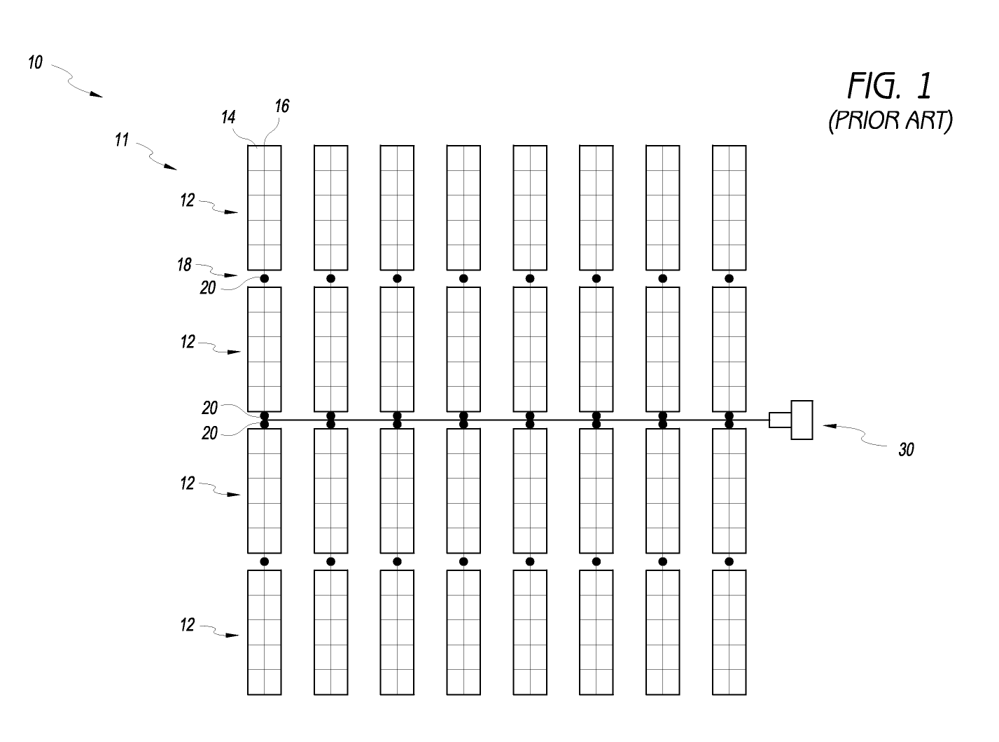

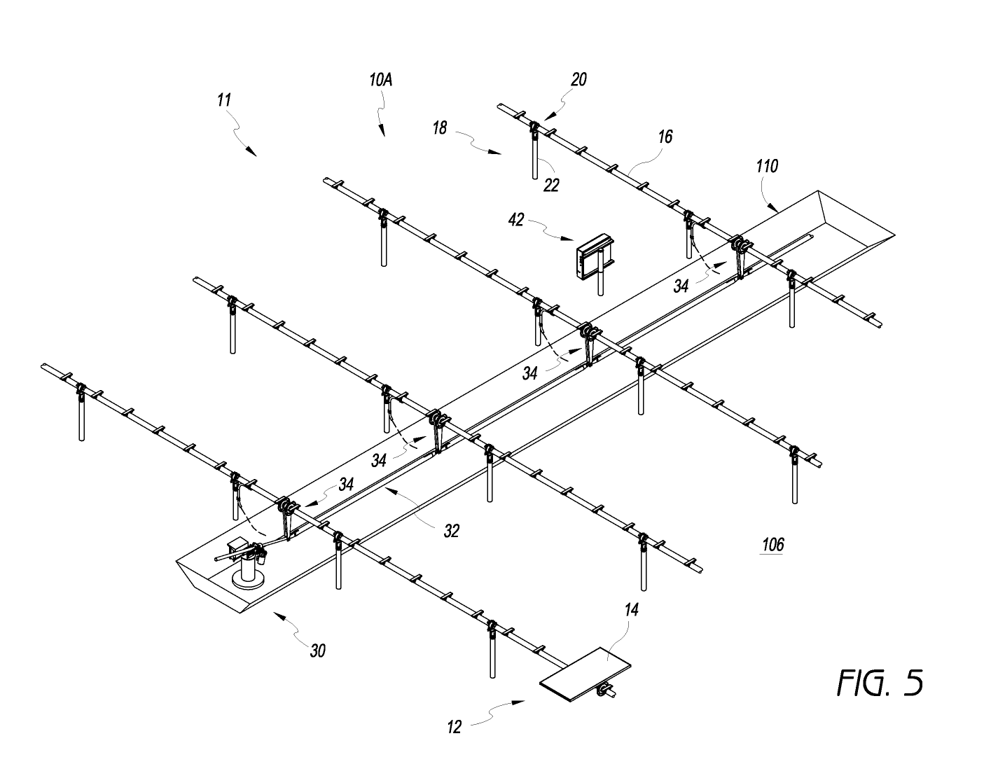

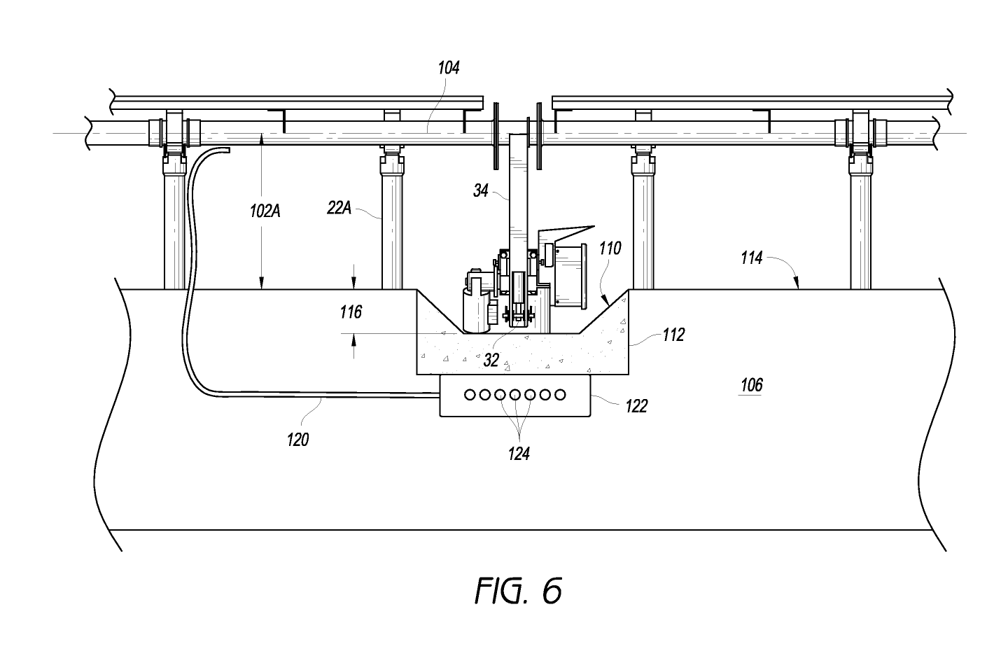

In the description set forth below, an example of a prior art a solar energy collection system 10 is described in the context of being formed by a plurality of solar collection modules, supported so as to be pivotally adjustable for sun-tracking purposes. The inventions described below, with reference to FIGS. 5 and 6, can be used with the solar collection system 10 described in FIGS. 1-4, as well as the variations and equivalents thereof. The system 10 can include a support member supporting a plurality of solar collection devices as well as wiring for connecting the various solar collection devices to each other and to other modules. The collection system 10 or the modules included in such a system, can be pivoted by a sun-tracking drive.

FIG. 1 illustrates the solar collection system 10, which can be considered an electricity farm. The solar collection system 10 includes a solar collector array 11 which includes a plurality of solar collection modules 12. Each of the solar collection modules 12 can include one or a plurality of solar collecting devices 14 supported by a drive shaft or torque tube 16. Each of the torque tubes 16 are supported above the ground by a support assembly 18. Each of the support assemblies 18 can include a pile and a bearing assembly 20.

With continued reference to FIG. 1, the system 10 can also include a tracking drive 30 connected to the torque tube 16 and configured to pivot the torque tube 16 so as to cause the collector devices 14 to track the movement of the sun. In the illustrated embodiment, the torque tubes 16 are arranged generally horizontally and the modules 12 are connected to each other, as more fully described in U.S. patent application Ser. No. 13/176,276, filed Jul. 5, 2011, the entire contents of which is hereby expressly incorporated by reference. However, inventions disclosed herein can be used in the context of other types of arrangements. For example, the system 10 can include a plurality of modules 12 that are arranged such that the torque tube 16 is inclined relative to horizontal, wherein the torque tubes 16 are not connected in an end to end fashion, such as the arrangement illustrated and disclosed in U.S. Patent Publication No. 2008/0245360. The entire contents of the 2008/0245360 patent publication is hereby expressly incorporated by reference. Further, the inventions disclosed herein can be used in conjunction with the systems that provide for controlled tilting about two axes, although not illustrated herein.

The solar collection devices 14 can be in the form of photovoltaic panels, thermal solar collection devices, concentrated photovoltaic devices, or concentrated thermal solar collection devices. In the illustrated embodiment, the solar collection devices 14 are in the form of non-concentrated, photovoltaic modules.

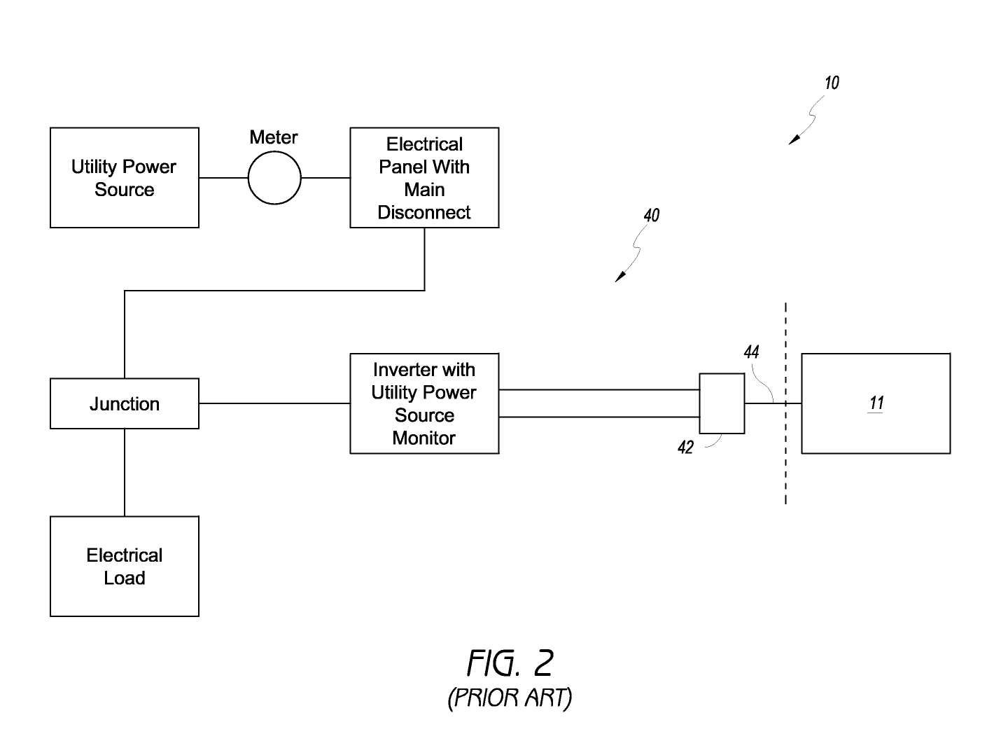

With reference to FIG. 2, solar collection system 10 can further include an electrical system 40 connected to the array 11. For example, the electrical system 40 can include the array 11 as a power source connected to a remote connection device 42 with power lines 44. The electrical system 40 can also include a utility power source, a meter, an electrical panel with a main disconnect, a junction, electrical loads, and/or an inverter with the utility power source monitor. The electrical system 40 can be configured and can operate in accordance with the descriptions set forth in U.S. Patent Publication No. 2010/0071744, the entire contents of which is hereby expressly incorporated by reference.

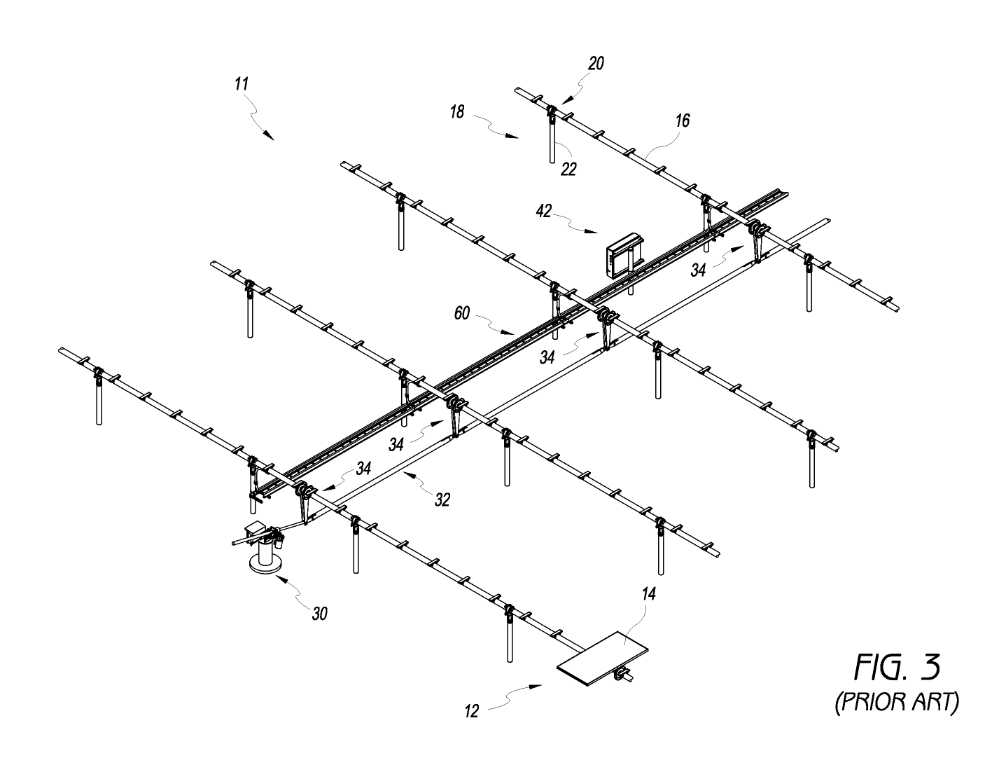

FIG. 3 illustrates the array 11 with all but one of the solar collection devices 14 removed. As shown in FIG. 3, each of the support assemblies 18 includes the bearing 20 supported at the upper end of a pile 22. The torque tube 16 can be of any length and can be formed in one or more pieces. The spacing of the piles 22 relative to one another, can be determined based on the desired limits on deflection of the torque tubes 16 between the support structures 18, wind loads, and other factors.

The tilt drive 30 can include a drive strut 32 coupled with the torque tube 16 in a way that pivots the torque tube 16 as the drive strut 32 is moved axially along its length. The drive strut 32 can be connected with the torque tube 16 with torque arm assemblies 34. In the illustrated embodiment, the torque arm assemblies 34 disposed at an end of each of the torque tube 16. The length of the torque arm assemblies 34 is determined to provide the desired leverage for visiting the torque tube 16 because the length of the torque arm assemblies 34 has a direct relationship on the amount of force that must be applied to the drive strut 32 in order to pivot the torque tube 16. Shorter torque arm assemblies 34 would require a higher force to be applied to the drive strut 32.

Additionally, the array 11 can include an electrical wire tray 60 supported by one or more of the piles 22, or by other means. The tray 60 can be used to support any of the wires that may be used for the operation of the system 10. For example, although not illustrated in FIG. 3, each of the solar collection devices 14 includes a power output device (not shown). Such power output devices can be in the form of direct current (DC), electrodes, or alternating current (AC) electrodes. Photovoltaic devices are typically designed to output a direct current. However, the modules 12 can include dedicated inverters (not shown) such that each module 12 outputs an alternating current. Further, a selected subset of the modules 12 can include inverters, combining the direct current of several modules 12 with one inverter. The outputs from each of these inverters can then be combined.

Thus, whether or not the modules 12 output DC or AC current, the modules 12 each have one or more wires extending from the module, to adjacent modules 12, and eventually to the tray 60, then eventually to the remote connection device 42, or other electrical equipment. The tray 60 is typically mounted above the ground at a distance of about 9-12 inches.

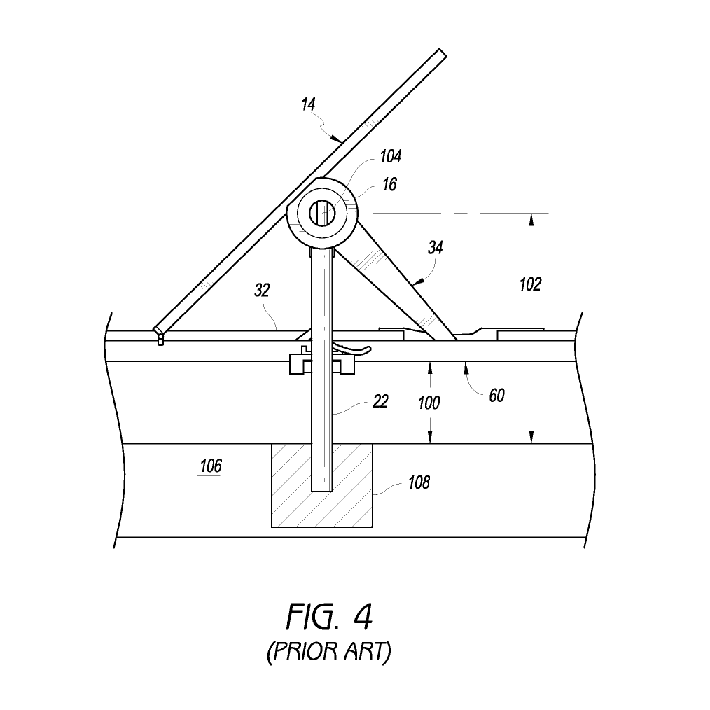

FIG. 4 illustrates, in an end view, the tray 60 supported by the pile 22, a clearance 100 which, as noted above, can be about 9-12 inches.

FIG. 4 also illustrates an optional maximum tilt angle for the module 14. The maximum tilt angle of the module 14 can be determined based on a number of factors, depending on the characteristics and performance of the system 10. For example, the maximum tilt angle of the module 14 can be chosen based on the position of the sun when the module 14 is first exposed to sunlight each day, or the angle at which the module 14 stops being exposed to light at the end of the day. Optionally, the maximum tilt angle can be chosen to provide a “safety” position designed to minimize the loads created during extreme weather, such as high winds. The maximum tilt angle of the module 14 can also be determined based on other factors. With the maximum tilt angle determined, the tilt drive 30 can be configured to drive the torque tubes 16 through the desired tilting motion and including the maximum tilt angles.

The piles 22, accordingly, are sized such that the modules 12 do not collide with the tray 60. Thus, the piles 22 are typically sized such that the edges of the solar modules 12 do not collide with the tray 60 when the modules 12 are at their maximum tilt positions.

With the final height of the pier 22 determined as such, the maximum wind loads for the site of installation of the system 10 can be determined, which provides the information sufficient to determine the appropriate strength of the piers 22. For example, one overriding calculation is the maximum torque applied to the piers 22 under a maximum wind load condition. The maximum torque applied to the piers 22 is directly proportional to the height 102 of the axis of rotation 104 of the torque tubes 16 above the ground 106. For example, the maximum torque applied to the piers 22 is the product of the height 102 times the maximum wind force created by the predetermined maximum wind speed and the aerodynamics of the modules 12 and torque tubes 16.

With the maximum torque calculated as such, the appropriate dimensions, i.e., thickness, cross-sectional shape, and depth of the pier 22 below the surface of the ground 106, as well as the magnitude of required cement or concrete 108 beneath the surface of the ground 106, will be required. At some sites, it may be necessary to pile drive the piers 22 to a required depth, as well as provide concrete foundations, wherein the piers 22 extend below the concrete 108. These techniques are well-known in the art.

With reference to FIGS. 5 and 6, as noted above, an aspect of at least one of the inventions disclosed herein includes the realization that significant cost savings can be achieved by modifying the ground surface existing at an installation site of a system 10, so as to provide clearance for drive struts 32 and torque arms 34, such that those components can, in at least one position during operation, extend below the surface of the surrounding ground. As such, the height of the piers 22 can be reduced, thereby reducing the calculated maximum torque applied to the piers 22, and thereby reducing the required material thicknesses, pile-driving depths, and required concrete foundations. In some installations, this reduction of pile height and installation requirements can produce cost savings that significantly outweigh the cost of altering the ground under the drive struts 32 and torque arms 34.

With reference to FIG. 5, an embodiment of the solar system in accordance with the present embodiment is illustrated therein, and is identified with the reference numeral 10A. The components of the system 10A can be similar or the same as the components of the system 10 illustrated in FIGS. 1-4, except as noted below. Thus, the components of the system 10A are identified using the same reference numerals of the system 10, except a letter “A” has been added thereto.

With continued reference to FIG. 5, the system 10A differs from the system 10 in that the tray 60 has been removed, with the associated wires being buried beneath the surface of the ground 106. Additionally, the system 10A is installed such that the drive struts 32 and/or portions of the torque arms 34 are positioned below the surface of the ground 106, in a trench 110, in at least one orientation during operation.

The trench 110 can have any configuration. In the illustrated embodiment, the trench 110 is in the shape of a trough-shaped trench. Other configurations can also be used.

In some embodiments, with reference to FIG. 6, the trench 110 can be formed by digging a straight-sided channel 112 into the ground 106, and backfilling with material so as to form a trough-shaped trench 110. The backfill can be any desired material appropriate for providing stable slopes to the trench 110, including but without limitation, cement, concrete, rocks, etc.

As shown in FIG. 6, the lower end of the torque arms 34 and the drive struts 32, in some orientations, are positioned lower than the upper surface 114 of the ground 106 adjacent to the torque arms 34 and the drive struts 32, during operation. In some embodiments, the trench 110 can have a sufficient depth 116 such that as the drive struts 32 are driven through their reciprocal sun tracking motion, the struts 32 rise above the upper surface of the ground 114.

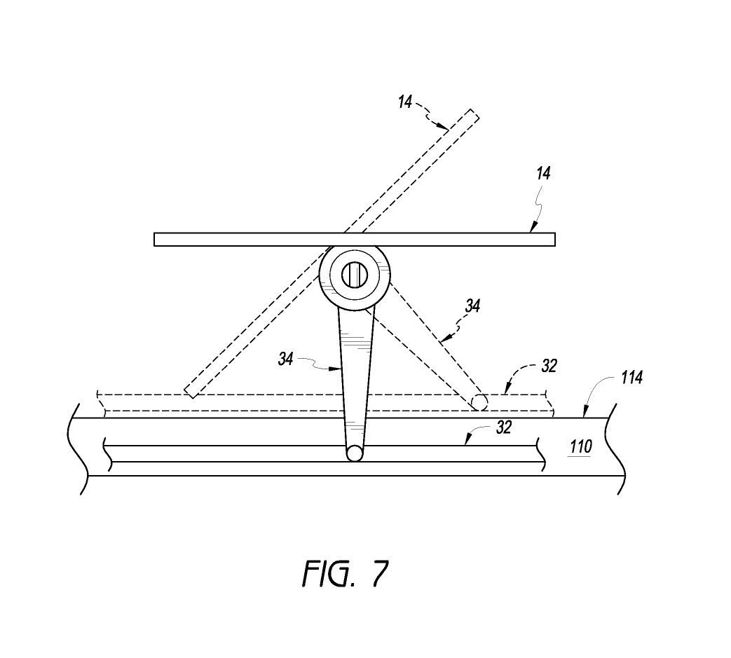

Thus, for example, as shown in FIG. 7, at a maximum tilt position (shown in dashed line), the drive strut 32 and lower end of the torque arm 34 can be above the upper surface of the ground 114. However, during other orientations, such as when the modules 12 are horizontal and the torque arms 34 are proximally vertical (referred to as the “noon position”, shown in solid line in FIG. 7), the lower end of the torque arms 34 and the drive struts 32 are below the surface of the ground 114. However, in some embodiments, the trench 110 can be sufficiently deep such that the lower ends of the torque arms 34 the drive struts 32 are below the surface of the ground 114 during all orientations during operation.

In either of the configurations disclosed above, the height of the piers 22A can be shorter than the height of the piers 22 illustrated in FIG. 4. Thus, when the system 10A is constructed at the same site as the system 10 of FIGS. 1-4, a significant cost savings can be achieved based on the ability to use shorter, and potentially thinner, piles 22A and other reduced installation and strength requirements associated with the shorter piles 22A. More specifically, the height 102A of the distance from the upper surface of the ground 114 to the rotational axis 104 of the torque tubes 16 is smaller than the height 102 of FIG. 4. Thus, the maximum torque applied to the piers 22A during a maximum wind speed event at the site, results in a lower maximum torque, thereby lowering the minimum strength requirements for the piers 22A and the associated installation requirements.

As noted above, the system 10A does not include the tray 60 used for the system 10. Thus, in the embodiment illustrated in FIGS. 5 and 6, wires 120 used for connecting the modules 12 together and to the remote connection device 42, are buried beneath the upper surface 114 of the ground. In some embodiments, the wires 120 can be buried below the trench 110. In some embodiments, a separate trench 122 can be dug beneath the trench 112. The wires 120, along with other direct current feeders 124, can be buried in the trench 122 and backfilled with the appropriate material. As such, the system 10A further avoids the limitations associated with the tray 60 illustrated in FIG. 3. Of course, the wires 120, 124 can be arranged in other configurations, including a trench separate from the trench 110, or other configurations.

While at least one exemplary embodiment has been presented in the foregoing detailed description, it should be appreciated that a vast number of variations exist. It should also be appreciated that the exemplary embodiment or embodiments described herein are not intended to limit the scope, applicability, or configuration of the claimed subject matter in any way. Rather, the foregoing detailed description will provide those skilled in the art with a convenient road map for implementing the described embodiment or embodiments. It should be understood that various changes can be made in the function and arrangement of elements without departing from the scope defined by the claims, which includes known equivalents and foreseeable equivalents at the time of filing this patent application.

What is claimed is:

1. A solar array comprising:
a pile configured to support a shaft, the pile having a lower end fixed to a ground;
at least a first shaft supported by the pile such that the shaft can pivot relative to the pile, about a pivot axis, the shaft supporting at least one solar module;
at least a first arm having a first and second ends, the first end being connected to the first shaft, the first arm extending from the first end along a substantially radial direction relative to the pivot axis such that the second end of the first arm moves through an arcuate path as the first shaft pivots about the pivot axis;
a trench formed in the upper surface of the ground wherein the upper surface of the ground surrounding the trench is generally planar, the trench being sized such as the second end moves from at least a first position above the generally planar upper surface of the ground to a second position within the trench and below the upper surface of the ground.

2. The solar array according to claim 1, wherein the pivot axis is orientated such that the solar module tracks movement of a sun as the shaft pivots about the pivot axis.

3. The solar array according to claim 1 additionally comprising a second shaft extending parallel to the first shaft and a second arm connected to the second shaft, the first and second arms being connected together with a drive strut.

4. The solar array according to claim 1 additionally comprising a drive motor and drive strut connected to the drive motor and to the first arm, the drive motor being configured to drive the drive strut through a reciprocating motion.

5. The solar array according to claim 4 additionally comprising a second shaft and a second arm extending from the second shaft, the drive motor being connected to the second arm.

6. The solar array according to claim 5 additionally comprising a second drive strut connecting the first arm with the second arm.

7. The solar array according to claim 6 additionally comprising at least a second solar module supported by the second shaft, at least a first electrical energy receiver module and at least one electrical conductor connecting the first and second solar modules with the first electrical energy receiver module, the electrical conductor being disposed in the trench.

8. The solar array according to claim 1 wherein the trench extends substantially perpendicular to the first shaft.

9. The solar array according to claim 1 additionally comprising a drive motor configured to drive the first arm in a reciprocating motion, the drive motor being disposed in the trench.

10. A solar array comprising:
a pile configured to support a shaft, the pile having a lower end fixed to a ground;
at least a first shaft supported by the pile such that the shaft can pivot relative to the pile, about a pivot axis, the shaft supporting at least one solar module;
at least a first arm having a first and second ends, the first end being connected to the first shaft, the first arm extending from the first end along a substantially radial direction relative to the pivot axis such that the second end of the first arm moves through an arcuate path as the first shaft pivots about the pivot axis;
means for allowing the second end to move from at least a first position above the generally planar upper surface of the ground to a second position below the upper surface of the ground without touching a surface of the ground.

11. The solar array according to claim 9 additionally comprising connecting means, extending below the first arm, for connecting the first solar module to another electrical component.

12. A method of constructing a solar array comprising:
fixing a pile to a ground;
supporting at least a first shaft with the pile such that the shaft can pivot relative to the pile, about a pivot axis, the shaft supporting at least one solar module;
connecting at least a first arm to the first shaft such that the first arm extends along a substantially radial direction relative to the pivot axis such that the second end of the first arm moves through an arcuate path as the first shaft pivots about the pivot axis;
forming a trench in the upper surface of the ground wherein the upper surface of the ground surrounding the trench is generally planar, the trench being sized such as the second end moves from at least a first position above the generally planar upper surface of the ground to a second position within the trench and below the upper surface of the ground.

13. The method according to claim 12 additionally comprising pivoting the first shaft such that the solar module tracks movement of a sun as the shaft pivots about the pivot axis.

14. The method according to claim 12 additionally comprising connecting a drive motor to the first arm and driving the first arm through a reciprocating motion with the drive motor.

15. The method according to claim 12 additionally comprising mounting a second shaft so as to extend parallel to the first shaft, connecting a second arm to the second shaft, and connecting the first and second arms with a drive strut.

16. The method according to claim 15 additionally comprising mounting at least a second solar module with the second shaft, connecting at least a first electrical energy receiver module to the first and second solar modules with at least one electrical conductor, and disposing the electrical conductor being disposed in the trench.

17. The method according to claim 12 additionally comprising digging the trench so as to extend substantially perpendicular to the first shaft.

18. The method according to claim 12 additionally comprising mounting a drive motor in the trench.

19. The method according to claim 12 reinforcing the trench to stabilize sloped sides of the trench.

20. The method according to claim 12 additionally comprising disposing a bridge across the trench.
